(19) United States
(12) Patent Application Publication
(10) Pub. No.: US 2003/0026308 A1
(43) Pub. Date: Feb. 6, 2003

(54) Surface emitting laser device

(76) Inventors: Norihiro Iwai, Tokyo (JP); Noriyuki Yokouchi, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/151,201

(22) Filed: May 17, 2002

(30) Foreign Application Priority Data
Aug. 2, 2001 (JP) 2001-235481
Sep. 20, 2001 (JP) 2001-286199

(51) Int. Cl. H01L 21/00; H01S 5/00; H01S 3/08

(52) U.S. Cl. 372/46; 372/45; 372/96; 438/22

(57) ABSTRACT

There is provided a surface emitting laser device of fundamental lateral mode oscillation that suppresses a resistor increase and that is favorable in reliability. A GaAs layer 16 having such a thickness as to exhibit a high reflection factor with respect to oscillation wavelength is formed on an upper DBR mirror. In addition, a groove having such a depth that the GaAs layer located directly under it has such a thickness as to exhibit a low reflection factor with respect to oscillation wavelength is formed on the GaAs layer in such a position as to stride an extension line of a boundary between an Al oxide layer and an AlAs layer. As a result, laser oscillation can be conducted only in a post region surrounded by the groove.

### BACKGROUND OF THE INVENTION

1. Field of the Invention

The present invention relates to a surface emitting laser device capable of performing fundamental lateral mode oscillation.

2. Description of Related Art

In a VCSEL (Vertical Cavity Surface Emitting Laser, hereafter simply referred to as surface emitting laser device), the direction of light resonance is perpendicular to a substrate plane as its name implies. The VCSEL attracts the attention as a communication light source and various other applications not to speak of the optical interconnection.

As its reason, there can be mentioned that the surface emitting laser device has advantages as compared with the conventional edge emitting laser device, such that a two-dimensional arrangement of devices can be formed easily, devices can be tested at a wafer level because it is not necessary to cleave to provide a mirror, and oscillation at an extremely low threshold value is possible and power dissipation is low because the volume of the active layer is markedly small.

Especially, in the surface emitting laser device, the longitudinal mode of the oscillation spectra has a feature that the fundamental lateral mode oscillation can be naturally obtained because the resonator length is extremely short. On the other hand, the edge emitting laser device has no control mechanism at all. Therefore, oscillation is caused at a plurality of high-order modes. The laser output oscillated at a plurality of high-order lateral modes becomes a factor causing remarkable degradation in proportion to the transmission distance at the time of optical transmission, and especially at the time of fast modulation. For the surface emitting laser device, various structures for causing laser oscillation at the fundamental lateral mode have been proposed.

The simplest method for obtaining the fundamental lateral mode is to adopt a structure in which the area of the emitting region is made small to such a degree that laser oscillation can occur only at the fundamental lateral mode. For example, for obtaining the fundamental lateral mode in the case of a surface emitting laser device having an oscillation wavelength in the 850 nm range, it is necessary to set the size of the emitting region equal to approximately 10 μm² or less. In the case of an oxide layer confining type structure, the current construction width, which controls the dimensions of the area of the emitting region is typically determined by an oxide layer formed by selectively oxidizing a peripheral portion of an AlAs layer as described later. For forming this oxide layer so as to attain an inside diameter to set the size of the emitting region equal to approximately 10 μm² or less as described above, precise oxidation control is required and consequently the product yield becomes worse. In addition, in such a narrow area, the device resistor increases, and an increase of the voltage applied to the surface emitting laser device is caused.

As a unit which obtains the fundamental lateral mode oscillation in the surface emitting laser device, therefore, a structure as shown in IEEE Photonics Technology Letters vol. 11, No. 12, December 1999 has been proposed (hereafter referred to as a first conventional art example). FIG. 7 is a schematic sectional view of the conventional surface emitting laser device.

For fabricating a surface emitting laser device 500 shown in FIG. 7, a lower DBR (Distributed Black Reflector) mirror 112 is first formed as a lower mirror on an n-type GaAs substrate 110 by using a MOCVD (metal organic chemical vapor deposition method) system. The lower DBR mirror 112 is a layer formed by laminating thirty-five pairs. Each of the thirty-five pairs has a laminated structure of an n-type Al_{0.9}Ga_{0.1}As and an n-type Al_{0.2}Ga_{0.8}As each having a thickness of λ/4n.

And over the lower DBR mirror 112, an active layer 121 interposed between an upper clad layer 122 and a lower clad layer 123 is formed. On a quantum well active layer 120 formed of these three layers, an upper DBR mirror 114 is further formed as an upper mirror. The upper DBR mirror 114 is a layer formed by laminating twenty-five pairs. Each of the twenty-five pairs has a laminated structure of a p-type Al_{0.9}Ga_{0.1}As and a p-type Al_{0.2}Ga_{0.8}As each having a thickness of λ/4n. The upper DBR mirror 114 further includes an AlAs layer 130 for forming a current constriction region in a subsequent process. In the lower DBR mirror 112 and the upper DBR mirror 114, λ is an oscillation wavelength of laser light and n is a refractive index of a semiconductor that forms each layer.

Subsequently, in a photolithography process and an etching process (it doesn't matter whether the etching is dry or wet), peripheral portions of the above-mentioned upper DBR mirror 114 (including the AlAs layer 130) and the quantum well active layer 120 are removed up to the top surface of the lower DBR mirror 112. Thereby, a circular mesa-post having a diameter of, for example, 30 μm is formed.

Subsequently, oxidation processing is conducted at a temperature of approximately 400° C. in an atmosphere of water vapor. The AlAs oxide layer 130 is selectively oxidized from the outside of the mesa-post to form an Al oxide layer 132. For example, if the Al oxide layer 132 takes the shape of a ring having a width of 10 μm, a central AlAs layer 131, i.e., a region (aperture) subject to current injection takes the shape of a circle having an area of approximately 80 μm² (a diameter of 10 μm).

The space around the mesa-post is filled up by polyimide 150. Thereafter, a ring-shaped electrode 109 having a width of approximately 5 μm is formed on an edge portion of the top of the mesa-post. The rear surface of the n-type GaAs substrate 110, i.e., the surface on which the above-mentioned semiconductor layer is not formed, is polished and suitably adjusted so as to set the thickness of the substrate equal to, for example, 200 μm. Thereafter, an electrode 108 is formed.

Finally, a ring-shaped groove 142 is formed inside the above-mentioned electrode 109. Specifically, the groove 142 is formed inside the Al oxide layer 132 so as to set the diameter of the post region 141 located inside the groove 142 equal to, for example, 5 μm. Actual formation of the groove 142 can be carried out by forming a pattern with, for example, an EB (electron beam) lithography aligner and conducting etching with RIBE (Reactive Ion Beam Etching). The formation of the groove 142 may be conducted immediately after the formation of the upper DBR mirror 114.

Usually, the number of lateral modes depends on the area of the above-mentioned AlAs layer 131. According to the structure shown in FIG. 7, the thickness of the upper DBR mirror 114 located directly under the ring-shaped groove 142 is made thinner by the depth of the groove 142. The reflection factor in that portion is lowered and the loss increases. As a result, in the post region 141 having a diameter of 5 μm that is located inside the groove 142 and that is not etched, laser oscillation of the fundamental lateral mode with laser oscillation of high-order modes suppressed is obtained. Furthermore, since the AlAs layer 131 narrowed down by the oxidation is larger in area than the post region 141, an increase in resistance and a rise in operation voltage can also be prevented.

As a unit which obtains fundamental lateral mode oscillation in the surface emitting laser device, there is proposed such a structure that a dielectric film serving as a phase adjustment layer is formed on, for example, the upper DBR mirror (hereafter referred to as second conventional art example), besides the structure of the conventional surface emitting laser device shown in FIG. 7. In the second conventional art example, a dielectric film is formed in a ring form on the top of the upper DBR mirror. Specifically, the dielectric film has a feature that it has such a film thickness as to effectively lower the reflection factor. Only directly under a region in which the dielectric film is not formed, laser oscillation occurs. Eventually, therefore, control of the oscillation lateral mode is implemented by not the dimension of the current constriction area, but the disposition position and thickness of the dielectric film formed on the upper DBR mirror.

In the above-mentioned first conventional art example, however, the upper DBR mirror 114 is etched in order to form the groove 142. Therefore, the AlGaAs layer that forms the upper DBR mirror 114 is temporarily exposed to the atmosphere. Since the AlGaAs layer is very easy to be oxidized, it is oxidized once it is exposed to the atmosphere. A natural oxide film is thus formed. In particular, this natural oxide film is unstable, the long term stability of the characteristics is not kept and there is a possibility of the reliability being affected.

On the other hand, in the structure of the above-mentioned second conventional art example, the phase adjustment is conducted by using only the dielectric layer. For example, in the case where the number of pairs of the upper DBR mirror is practical 25, the reflection factor of the region in which the dielectric layer is not formed is 99.94%, whereas the reflection factor of the region in which the dielectric layer is formed is approximately 98.5%. Since the reflection factor difference, i.e., loss difference is small, oscillation of high-order modes occurs together with the fundamental lateral mode when a high current is injected. Thus there is a problem that so-called multi-mode oscillation occurs.

### SUMMARY OF THE INVENTION

It is an object of the present invention to provide a surface emitting laser device that suppresses an increase in resistance and operation voltage, that has favorable reliability, and that conducts the fundamental lateral mode oscillation stably.

In accordance with a first aspect of the present invention, a surface emitting laser device having such a layer structure that a lower mirror (which corresponds to a lower DBR mirror 12 described later), an active layer (which corresponds to a quantum well active layer 20 described later), and an upper mirror (which corresponds to an upper DBR mirror 14 described later) are laminated in a cited order, and including a current constriction layer (which corresponds to an AlAs layer 30 described later) in the lower mirror or the upper mirror includes a semiconductor layer, and the semiconductor layer includes: a first region exhibiting a first reflection factor with respect to oscillation laser light, the first region being provided on the upper mirror, the first region being provided at least inside a boundary face of a current constriction region (which corresponds to an AlAs layer 31 described later) defined by the current constriction layer; and a second region exhibiting a second reflection factor with respect to the oscillation laser light.

According to the first aspect of the present invention, for example, laser light of the fundamental lateral mode can be emitted from the first region in the case where the second reflection factor is sufficiently smaller than the first reflection factor, the sizes of the first and second regions are smaller than the restriction imposed by the current constriction region, and the size of the first region is approximately the same as the fundamental lateral mode.

In accordance with a second aspect of the present invention, in a surface emitting laser device according to the first aspect of the present invention, the first region (which corresponds to a post region 41 described later) has a thickness that is substantially equal to (2+1)/4n times (where n is a refractive index of the semiconductor layer, and i is an integer) a wavelength of the oscillation laser light, and the second region (which corresponds to a groove 42 described later) has a thickness that is substantially equal to 2j/4n times (where n is a refractive index of the semiconductor layer, and j is a natural number) the wavelength of the oscillation laser light.

According to the second aspect of the present invention, the semiconductor layer is made to function as such a phase adjustment layer of oscillation laser light that the reflection factor largely differs according to its thickness, and thereby only the reflection factor of the second region can be lowered without affecting the reflection factor of the first region and laser oscillation can be caused selectively in the first region.

In accordance with a third aspect of the present invention, in a surface emitting laser device according to the first aspect of the present invention, the semiconductor layer is covered with a dielectric film, the first region (which corresponds to a groove 47 described later) has a thickness that is substantially equal to 2i/4n times (where n is a refractive index of the semiconductor layer, and i is a natural number) a wavelength of the oscillation laser light, the second region has a thickness that is substantially equal to (2j+1)/4n times (where n is a refractive index of the semiconductor layer, and j is an integer) the wavelength of the oscillation laser light, and the dielectric film (which corresponds to a dielectric film 19 described later) has a refractive index smaller than that of the semiconductor layer, and a thickness that is substantially equal to (2k+1)/4ns times (where ns is a refractive index of the dielectric film and k is an integer) the wavelength of the oscillation laser light.

According to the third aspect of the present invention, the thickness of the dielectric film that covers the top of the semiconductor layer is set substantially equal to (2k+1)/4ns times the wavelength of the oscillation laser light. Accordingly, the dielectric film can be made to function as a phase inversion layer. As a result, only the reflection factor of the second region can be lowered without affecting the reflection factor of the underlying first region. Laser oscillation can be caused selectively in the first region.

Other objects and features of this invention will become understood from the following description with reference to the accompanying drawings.

### BRIEF DESCRIPTION OF THE DRAWINGS

FIG. 1 is a schematic sectional view of a surface emitting laser device according to a first embodiment of the present invention;

FIG. 2 is a diagram showing a reflection factor as a function of a thickness of a GaAs layer for description of the surface emitting laser device according to the first embodiment of the present invention;

FIG. 3 is a schematic sectional view of another example of a surface emitting laser device according to the first embodiment of the present invention;

FIG. 4 is a schematic sectional view of a surface emitting laser device according to a second embodiment of the present invention;

FIG. 5 is a schematic sectional view of a surface emitting laser device according to a third embodiment of the present invention;

FIG. 6 is a diagram showing a reflection factor as a function of a thickness of a GaAs layer for description of the surface emitting laser device according to the third embodiment of the present invention; and

FIG. 7 is a schematic sectional view of a conventional surface emitting laser device.

### DESCRIPTION OF THE PREFERRED EMBODIMENTS

Hereafter, embodiments of a surface emitting laser device according to the present invention will be described in detail by referring to the drawing. The present invention is not limited by the embodiments.

First, a surface emitting laser device according to a first embodiment will be described. FIG. 1 is a schematic sectional view of a surface emitting laser device according to the first embodiment. Hereafter, especially the structure of a surface emitting laser device of a 850 nm range will be described.

For fabricating a surface emitting laser device 100 according to the first embodiment shown in FIG. 1, a lower DBR mirror 12 is first formed on an n-type GaAs substrate 10 by using a MOCVD system. The lower DBR mirror 12 is a layer formed by laminating thirty-five pairs. Each of the thirty-five pairs has a laminated structure of an n-type Al_{0.9}Ga_{0.1}As and an n-type Al_{0.2}Ga_{0.8}As each having a thickness of λ/4n in the same way as the first conventional art example.

Subsequently, over the lower DBR mirror 12, a clad layer 22, an SCH-MQW active layer 21, and a clad layer 23 are formed on the lower DBR mirror 12 one after another. On a quantum well active layer 20 formed of these three layers, an upper DBR mirror 14 is further formed. The upper DBR mirror 14 is a layer formed by laminating twenty-five pairs. Each of the twenty-five pairs has a laminated structure of a p-type Al_{0.9}Ga_{0.1}As and a p-type Al_{0.2}Ga_{0.8}As each having a thickness of λ/4n. The upper DBR mirror 14 further includes an AlAs layer 30 for forming a current constriction region in a subsequent process.

In the surface emitting laser device according to the first embodiment, a GaAs layer 16 having a thickness of 3λ/4n (approximately 150 nm) is formed on the upper DBR mirror 14. In addition, a ring-shaped groove 42 having a depth of 50 nm and a width of 5 μm is formed on the GaAs layer 16. Specifically, the groove 42 is formed in such a position as to stride a boundary face between an Al oxide layer 32 and an AlAs layer 31 (in other words, an inner circumference face of the ring-shaped Al oxide layer 32). As a result, a post region 41 having a diameter of approximately 4 μm is formed.

If the thickness of a portion of the GaAs layer 16 located directly under the groove 42 is set equal to 2λ/4n, then mismatching of the phase of incident light occurs between the GaAs layer 16 and its groove 42. In a portion located directly under the groove 42, the effective reflection factor can be lowered. In other words, laser oscillation in that portion can be suppressed. To be concrete, the thickness of the GaAs layer 16 located directly under the groove 42 is set equal to 2iλ/4n, and the thickness of a portion of the GaAs layer 16 located directly under the post region, in which the groove 42 is not formed, is set equal to (2i+1)λ/4n. In each of the above-mentioned configurations of the lower DBR mirror 12, the upper DBR mirror 14, and the GaAs layer 16, λ is an oscillation wavelength, n is a refractive index of each layer, and i is a natural number.

Subsequently, in a photolithography process and an etching process (it doesn't matter whether the etching is dry or wet) peripheral portions of the above-mentioned GaAs layer 16 and upper DBR mirror 14 (including the AlAs layer 30) are removed up to the top surface of the quantum well active layer 20. Specifically, etching is conducted so as to form a circular mesa-post (having a diameter of, for example, 40 μm) having the above-mentioned post region 41 located in the center thereof.

Subsequently, oxidation processing is conducted at a temperature of approximately 400° C. in an atmosphere of water vapor. The AlAs oxide layer 30 is selectively oxidized from the outside of the mesa-post to form an Al oxide layer 32. For example, if the Al oxide layer 32 takes the shape of a ring formed so as to have a width of 16.5 μm, a central AlAs layer 31, i.e., a region (aperture) subject to current injection takes the shape of a circle having an area of approximately 40 μm² (a diameter of 7 μm).

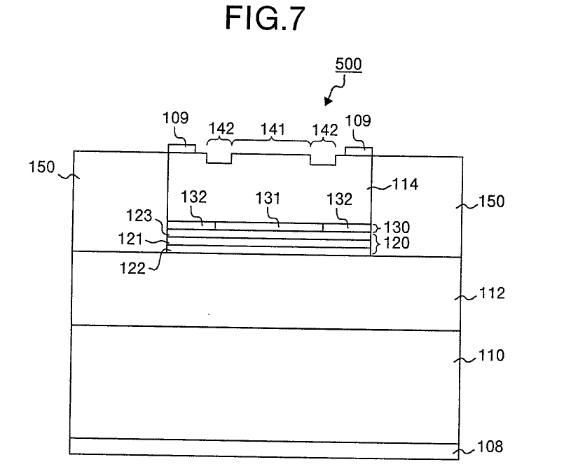

And a ring-shaped electrode 9 having a width of approximately 5 μm is formed on an edge portion of the top of the GaAs layer 16 located on the upper portion of the mesa-post. The rear surface (the n-type GaAs substrate 10) side is polished and suitably adjusted so as to set the thickness of the substrate equal to, for example, 200 μm. Thereafter, an electrode 8 is formed. Subsequently, the outer side wall portion of the mesa-post and the surface of the exposed quantum well active layer 20 are covered by a dielectric film 17 (of SiN or the like). By the way, on the above-mentioned dielectric film 17, the space around the mesa-post may be filled up with polyimide as shown in FIG. 7.

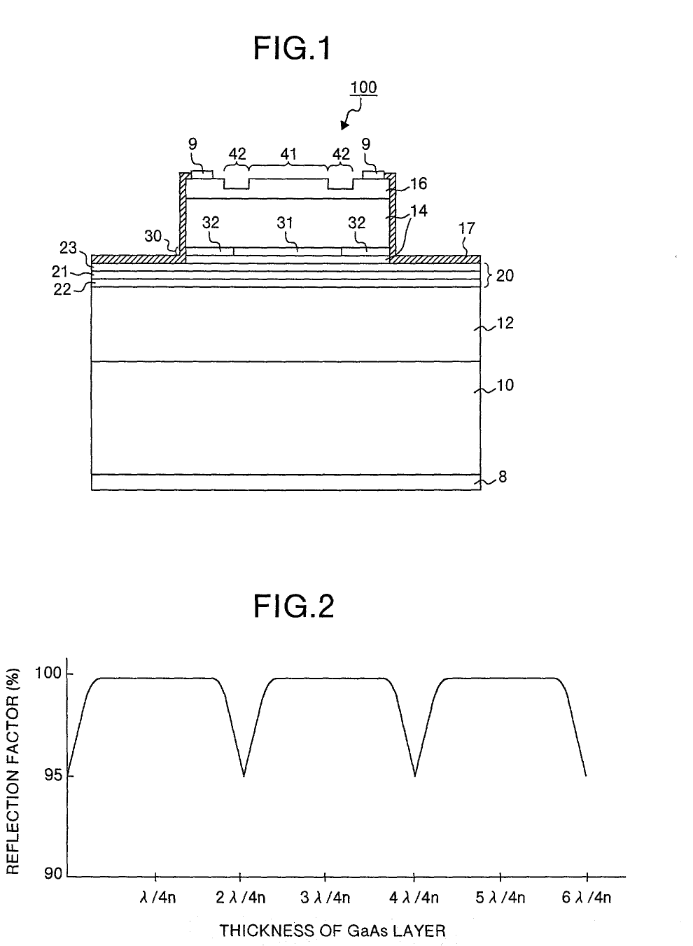

FIG. 2 is a diagram showing a reflection factor as a function of a thickness of a GaAs layer for description of the surface emitting laser device according to the first embodiment of the present invention. As shown in FIG. 2, the effective reflection factor of the upper DBR mirror 14 sensitive to laser light assumes a peak value when the thickness of the GaAs layer 16 is (2j+1)λ/4n. The reflection factor is minimized when the thickness of the GaAs layer 16 is 2jλ/4n (valley position). By thus controlling the thickness of the GaAs layer 16 by taking λ/4n as the unit, it is possible to set the GaAs layer 16 function as a phase adjustment layer with respect to laser oscillation light. As a result, the effective reflection factor can be controlled in some range. In the trial calculation of the reflection factor shown in FIG. 2, the number of pairs of the upper DBR mirror 14 is set equal to 25. The character j represents an integer.

To be concrete, the reflection factor in the peak position becomes approximately 99.94% and the reflection factor in the valley position becomes approximately 95%. Estimating the resonator loss (mirror loss) from these values, it becomes approximately 30 cm⁻¹ in the peak position and approximately 250 cm⁻¹ in the valley position. It is appreciated from this that the mirror loss in the region of the ring-shaped groove 42 becomes as large as approximately eight times, and oscillation in this region is completely suppressed. In other words, laser oscillation occurs only in the post region 41 (region of 4 μm) surrounded by the groove 42. As a result, oscillation in the fundamental lateral mode is obtained. The positions of the peak and valley of the reflection factor occur periodically and repetitively with respect to the thickness of the GaAs layer 16. Therefore, similar effects are obtained in each period. In the case where the oscillation wavelength is 860 nm or less, however, the oscillation is absorbed by the GaAs layer 16. Therefore, it is not desirable to set the GaAs layer 16 too thick.

In the GaAs layer 16, it is not always necessary that the difference between the thickness of the post region 41 and the thickness directly under the groove 42 is λ/4n as in the above-mentioned example. It is sufficient that the thickness of the post region 41 is equal to an odd number times as large as λ/4n and the thickness directly under the groove 42 is an even number times as large as λ/4n. For example, it is also possible to set the thickness of the post region 41 equal to 5 λ/4n and set the thickness directly under the groove 42 equal to 2λ/4n (set the depth of the groove 42 equal to 3λ/4n).

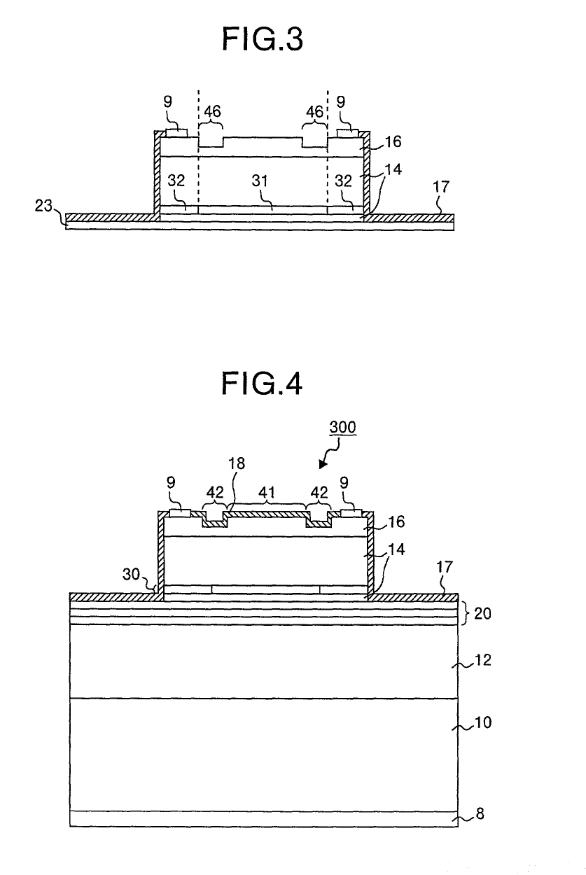

In the structure diagram shown in FIG. 1, there is shown such a state that the center of the groove 42 is located on an extension line of a boundary between the Al oxide layer 32 and the AlAs layer 31. As shown in FIG. 3, however, it is possible that the outer edge of a ring-shaped groove 46 is located on an extension of the boundary line or on the outer circumference side. Instead of the GaAs layer 16, another semiconductor layer of AlGaAs, InGaP, AlGaInP, GaInAsP or the like may also be used.

According to the surface emitting laser device according to the first embodiment heretofore described, the GaAs layer 16, which is matched in phase to the oscillation laser light and which has such a thickness as not to affect the reflection factor, is formed on the upper DBR mirror 14. In addition, the groove 42 having such a depth that the GaAs layer 16 located directly under it mismatches in phase to the oscillation laser light and exhibits a low reflection factor is formed on the GaAs layer 16 in such a position as to stride the extension line of the boundary between the Al oxide layer 32 and the AlAs layer 31. Therefore, laser oscillation can be conducted only in the post region 41 surrounded by the groove 42. In other words, the emitting region can be controlled with the size of the post region 41. In the conventional art, other characteristics are degraded by using the current constriction width alone. In the present invention, however, oscillation of the fundamental lateral mode can be implemented easily without sacrificing other characteristics.

Furthermore, unlike the first convention art example, the AlGaAs layer of the upper DBR mirror is not exposed. Therefore, a device having favorable reliability can be fabricated. Furthermore, the phase adjustment using the GaAs layer 16 can lower the reflection factor greatly as compared with lowering of the reflection factor conducted by forming the dielectric film on the upper DBR mirror as in the second conventional art example. As a result, the problem of the multi-mode oscillation at the time of high current injection is also solved.

In addition, the GaAs layer 16 can be utilized as a contact layer that makes the electric connection to the electrode 9 more favorable. Specifically, the remaining GaAs layer portion located directly under the groove 42 can sufficiently diffuse the current supplied from the electrode 9. As a result, it is possible to lower the device resistance and prevent uneven injection of the current.

In the foregoing description, the post region 41 serving as the emitting region is formed by forming the groove 42. However, it is sufficient that a convex-shaped post that satisfies the above-mentioned thickness relation is formed at least inside as compared with the Al oxide layer 32 serving as the current constriction portion.

In the above-mentioned example, the AlAs layer 31, i.e., the aperture formed by the current constriction layer takes the shape of a circle having a diameter of 7 μm. Preferably, the diameter is in the range of 5 to 10 μm. If the diameter is less than 5 μm, then the device resistance remarkably increases. If the diameter is greater than 10 μm, then oscillation occurs at high-order modes and the device characteristics are degraded. More preferably, the diameter is in the range of 6 to 7 μm.

In the above-mentioned example, the diameter of the post region 41 is set equal to approximately 4 μm. Preferably, the diameter of the post region 41 is less than the diameter of the aperture and in the range of 3.0 to 5.5 μm. If the diameter is less than 3.0 μm, then a loss is caused in the fundamental lateral mode and the device characteristics are degraded. If the diameter is greater than 5.5 μm, then oscillation of higher modes occurs. More preferably, the diameter of the post region 41 is in the range of 3.5 to 4.0 μm.

A surface emitting laser device according to a second embodiment will now be described. The surface emitting laser device according to the second embodiment has a feature that a dielectric film that functions as a protection film is formed on the GaAs layer 16 of the surface emitting laser device described earlier with reference to the first embodiment.

When fabricating or handling the surface emitting laser device, it is necessary to protect a laser light emission surface from external mechanical or chemical contamination. For example, a plurality of surface laser emitting devices can be formed on a semiconductor wafer in a two-dimensional array form. Therefore, it is possible to put together as many plurality of surface emitting laser devices as determined according to the application and cut out them from the semiconductor wafer. At the time of the cutting out, there is conducted dicing, which is typically conducted in the later process of semiconductor chips. However, there is a possibility that particles or other impurities caused by the dicing stick to the emission surface of the surface emitting laser device. As a countermeasure thereof, therefore, it is desirable to form a protection film on the emission surface.

FIG. 4 is a schematic sectional view of a surface emitting laser device according to the second embodiment. In FIG. 4, the same components as those of FIG. 1 are denoted by like numerals, and description thereof will be omitted. A surface emitting laser device 300 shown in FIG. 4 differs from the surface emitting laser device shown in FIG. 1 in that a dielectric film 18 is formed on the GaAs layer 16 serving as the laser emission surface. The dielectric film 18 is made of a material having a refractive index smaller than that of GaAs, and the dielectric film 18 is set equal to 2iλ/4ns in thickness, where λ is an oscillation length, ns is a refractive index of the dielectric film 18, and i is a natural number. As the material of the dielectric film 18, SiN, SiO₂, Al₂O₃, TiO₂, AlN, a-Si, or the like can be used.

Even if the dielectric film 18 is formed on the GaAs layer 16 as the protection film, therefore, a phase shift is not caused in oscillation laser light by the existence of the dielectric film 18 and only the post region 41 serves as the emission region.

According to the surface emitting laser device according to the second embodiment, the dielectric film 18 is formed as the protection film on the GaAs layer 16 serving as the laser emission surface in the surface emitting laser device of the first embodiment. Accordingly, oscillation of the fundamental lateral mode in the post region 41 of the GaAs layer 16 can be implemented. In addition, the surface of the GaAs layer 16 can be prevented from being directly contaminated, and the yield can be improved. Furthermore, degradation caused by the exposure to the atmosphere of the air can also be reduced. As a result, long term reliability can be ensured.

Furthermore, in the case where there is adopted such a structure as to cover the side wall portion of the mesa-post and the surface of the quantum wall active layer 20 with the dielectric film 17, the formation of the dielectric film 17 and the formation of the dielectric film 18 on the GaAs layer 16 can also be conducted simultaneously in the same process. Occurrence of a new process can thus be avoided.

A surface emitting laser device according to a third embodiment will now be described. The surface emitting laser device according to a third embodiment has a feature in the GaAs layer 16 of the surface emitting laser device described earlier with reference to the first embodiment that the convex-concave relation between the groove 42 and the post region 41 is inverted and in addition there is formed thereon a dielectric film having such a thickness as to invert the phase of the oscillation laser.

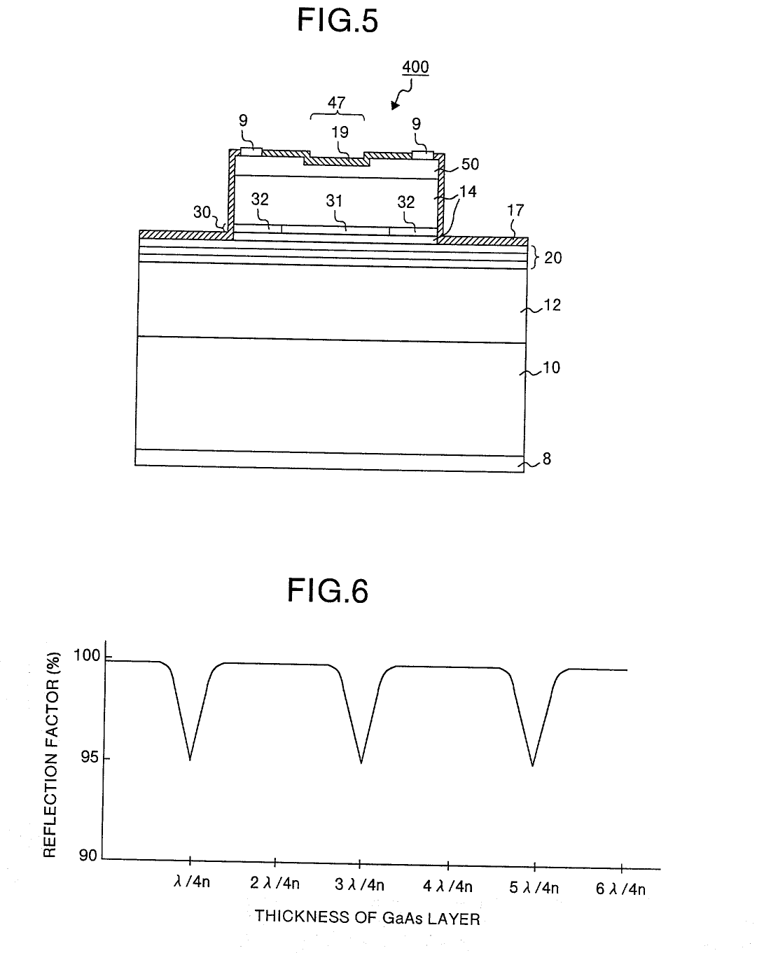

FIG. 5 is a schematic sectional view of the surface emitting laser device according to the third embodiment. In the ensuing description as well, a structure of a surface emitting laser device in the 850 nm range will be described in the same way as the first embodiment. In FIG. 5, the same components as those of FIG. 1 are denoted by like numerals, and description thereof will be omitted. A surface emitting laser device 400 shown in FIG. 5 differs from the surface emitting laser device shown in FIG. 1 in a position of a groove formed on a GaAs layer 50, which is in turn formed on the upper DBR mirror 14, and in that a dielectric film 19 is formed on a top surface of the GaAs layer 50.

To be concrete, the upper DBR mirror 14 is formed in accordance with the method described earlier with reference to the first embodiment. Thereafter, a GaAs layer 50 having a thickness of 3λ/4n (approximately 150 nm) is formed. Thereafter, a circular groove 47 having a diameter of 4 μm and a depth of 50 nm is formed in a center portion of the GaAs layer 50. Specifically, the groove 47 is formed so as to be located in the circle of the AlAs layer 31.

As for the relation between the GaAs layer 50 and the groove 47, the thickness of a portion of the GaAs layer 50 located directly under a region having no groove 47 is set equal to (2i+1)λ/4n, and the thickness of a portion of the GaAs layer 50 located directly under the groove 47 is set equal to 2iλ/4n, where λ is an oscillation length, n is a refractive index of the GaAs layer 50, and i is a natural number.

The top surface of the GaAs layer 50 inclusive of the groove 47 is covered by the dielectric film 19. The dielectric film 19 is made of a material having a refractive index smaller than that of GaAs, and the dielectric film 18 is set equal to (2k+1)λ/4ns in thickness, where λ is an oscillation length, ns is a refractive index of the dielectric film 19, and i is a natural number. As a result, the dielectric film 19 functions as a phase inversion layer. As the material of the dielectric film 19, SiN, SiO₂, Al₂O₃, TiO₂, AlN, a-Si, or the like can be used.

The dielectric film 17 functions as a protection film for preventing oxidation or the like. The dielectric film 17 may be formed by using the same material as that of the dielectric film 19 simultaneously in the same process.

FIG. 6 is a diagram showing a reflection factor as a function of a thickness of a GaAs layer for description of the surface emitting laser device according to the third embodiment of the present invention. As shown in FIG. 6, the effective reflection factor of the upper DBR mirror 14 sensitive to laser light assumes a peak value when the thickness of the GaAs layer 50 is 2iλ/4n. The reflection factor is lowered when the thickness of the GaAs layer 50 is (2j+1)λ/4n (valley position). Since the dielectric film 19 having the thickness of (2k+1)λ/4ns is formed on the top surface of the GaAs layer 50, phase inversion occurs, and the relation of the peak positions and the valley positions is inverted as compared with FIG. 2. Eventually, laser oscillation occurs only in the region of the groove 47. As a result, oscillation in the fundamental lateral mode is obtained. The character i is a natural number, and j represents an integer.

As described earlier with reference to the first embodiment, the positions of the peak and valley of the reflection factor occur periodically and repetitively with respect to the thickness of the GaAs layer 50. Therefore, similar effects are obtained in each period.

In the GaAs layer 50, it is not always necessary that the difference between the thickness of the portion of the GaAs layer 50 located directly under the region having no groove 47 and the thickness of the portion of the GaAs layer 50 located directly under the groove 47 is λ/4n as in the above-mentioned example. It is sufficient that the thickness of the portion of the GaAs layer 50 located directly under the region having no groove 47 is equal to an odd number times as large as λ/4n and the thickness of the portion of the GaAs layer 50 located directly under the groove 47 is an even number times as large as λ/4n. For example, it is also possible to set the thickness of the portion of the GaAs layer 50 located directly under the region having no groove 47 equal to 5λ/4n and set the thickness of the portion of the GaAs layer 50 located directly under the groove 47 equal to 2λ/4n (set the depth of the groove 47 equal to 3λ/4n).

According to the surface emitting laser device according to the third embodiment heretofore described, the GaAs layer 50, which is matched in phase to the oscillation laser light and which has such a thickness as not to affect the reflection factor, is formed on the upper DBR mirror 14. In addition, the groove 47 having such a depth that the GaAs layer 50 located directly under it has such a thickness as to just invert the phase with respect to the oscillation laser light is formed on the GaAs layer 50 in such a position as to correspond to the inside of the circle of the AlAs layer 31. In addition, they are covered by the dielectric film that inverts the phase of the oscillation laser light. Therefore, laser oscillation can be caused only in the groove 47. In other words, the emission region can be controlled with the size of the groove 47. In the conventional art, other characteristics are degraded when the current constriction width control alone is used. On the other hand, in the present invention, the oscillation of the fundamental lateral mode can be implemented easily without sacrificing other characteristics.

In the first embodiment, the post region 41 is used as the emission region. In the structure according to the third embodiment, however, the region of the groove 47 is used as the emission region. Inevitably, therefore, the thickness of the GaAs layer 50 serving as the emission region can be made thinner than that in the first embodiment. Even if the oscillation wavelength is 860 nm or less, absorption of laser light can be suppressed to a low value.

If there is satisfied, in the structure shown in FIG. 5 in the above-mentioned third embodiment even if the dielectric film 19 is not provided, such a relation that the thickness of the portion of the GaAs layer 50 located directly under the region having no groove 47 is equal to an odd number times as large as λ/4n and the thickness of the portion of the GaAs layer 50 located directly under the groove 47 is an even number times as large as λ/4n, then effects similar to the first embodiment can be brought about. For example, it is possible to set the thickness of the portion of the GaAs layer 50 located directly under the region having no groove 47 equal to 4λ/4n and set the thickness of the portion of the GaAs layer 50 located directly under the groove 47 equal to 3λ/4n (set the depth of the groove 47 equal to λ/4n).

In the above-mentioned example, the diameter of the groove 47 is set equal to approximately 4 μm. Preferably, however, the diameter in the range of 3.0 to 5.5 μm suffices.

The first to third embodiments have heretofore been described by taking a laser of 850 nm range as an example. However, the structure of the surface emitting laser device according to the present invention can also be applied to surface emitting laser devices of other wavelength ranges For example, the structure of the surface emitting laser device according to the present invention can also be applied to surface emitting laser devices of 1.3 μm range using a GaInNAs material in the active layer.

In the structures shown in FIGS. 1, 4 and 5, the n-type lower DBR mirror, the quantum well active layer, and the p-type upper DBR mirror are laminated on the n-type GaAs substrate one after another. As a matter of course, however, the present invention can be applied to such a structure that the conductivity type of each semiconductor layer is inverted. In that case, however, the current constriction layer (the AlAs layer 31 and the Al oxide layer 32) is formed in a p-type lower DBR mirror, and the quantum well active layer is formed over it.

In the surface emitting laser device according to the present invention, the emission region which has heretofore been controlled by the current constriction width can be controlled by a size determined by the post region or the groove of the semiconductor layer (such as the GaAs layer) having a narrower width. In the conventional art, other characteristics are degraded by using the current constriction width alone. The present invention brings about an effect that oscillation of the fundamental lateral mode can be implemented easily without sacrificing other characteristics.

Furthermore, in the surface emitting laser device according to the present invention, exposition of a part of the upper DBR mirror to the air caused by forming the groove directly on the upper DBR mirror is avoided unlike the convention art. Therefore, a device having favorable reliability can be fabricated. In addition, the phase adjustment using the semiconductor layer (such as the GaAs layer) can lower the reflection factor greatly as compared with lowering of the reflection factor conducted by forming the dielectric film and the upper DBR mirror. As a result, there is brought about an effect that the multi-mode oscillation at the time of high current injection can be prevented.

Furthermore, In the surface emitting laser device according to the present invention, the electrode is formed on the semiconductor layer (such as the GaAs layer). Therefore, the semiconductor layer can be utilized as a contact layer that makes the electric connection to the electrode more favorable. Specifically, the remaining semiconductor layer portion located directly under the groove formed on the semiconductor layer can sufficiently diffuse the current supplied from the electrode. As a result, there is brought about an effect that it is possible to lower the device resistance and also prevent uneven injection of the current.

Furthermore, In the surface emitting laser device according to the present invention, the dielectric film can be formed as the protection film on the semiconductor layer (such as the GaAs layer) serving as the laser emission surface. Accordingly, there is brought about an effect that the surface of the semiconductor layer can be prevented from being directly contaminated, and the yield can be improved.

Furthermore, In the surface emitting laser device according to the present invention, the dielectric film formed on the semiconductor layer (such as the GaAs layer) is made to function as a phase inversion layer. As a result, the region of the groove can be used as the emission region. Inevitably, therefore, the thickness of the semiconductor layer serving as the emission region can be made thinner than that of the case where the post region is used as the emission region. There is brought about an effect that absorption of laser light can be suppressed to a low value even in the case where the oscillation wavelength is 860 nm or less.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of fabricating a semiconductor laser, comprising:
forming an active layer configured to emit light of wavelength λ;
forming a mirror above said active layer; and
forming a cap above said mirror having a refractive index n wherein said cap is at least about λ/2n thick, wherein said cap is configured such that inner and outer regions of said cap have different reflection factors to light emitted by said active layer.

2. The method of claim 1, additionally comprising forming a current constriction region near said active layer.

3. The method of claim 2, wherein a diameter of said current constriction region is greater than a diameter of said inner region.

4. The method of claim 3, wherein said current constriction region near said active layer has a diameter of about 5 to 10 microns.

5. The method of claim 3, wherein said current constriction region near said active layer has a diameter of about 6 to 7 microns.

6. The method of claim 4, wherein said cap comprises an inner area having a diameter of about 5.5 microns.

7. The method of claim 4, wherein said inner area has a diameter of about 4 microns.

8. The method of claim 1, wherein said cap comprises an inner area having a thickness of about i×λ/4n where i is an odd integer greater than 1.

9. The method of claim 8, wherein said cap comprises an outer area radially surrounding said inner area and having a thickness of about j×λ/4n where j is an even integer.

10. The method of claim 9, wherein the thickness of said inner area is greater than the thickness of said outer area.

11. The method of claim 1, wherein said cap consists essentially of a material selected from the group consisting of (GaAs, AlGaAs, InGaP, AlGaInP or GaInAsP.

12. The method of claim 1, wherein
said semiconductor laser is formed on a GaAs substrate, and
said active layer is configured to emit laser light having a wavelength from about 700 to 1000 nm.

13. The method of claim 1, wherein
said semiconductor laser is formed on a GaAs substrate, and
said active layer is configured to emit laser light having a wavelength from about 1200 to 1600 nm.

14. The method of claim 1, further comprising depositing a dielectric film on a top surface of said cap so that said dielectric film induces a phase inversion on incident light.

15. The method of claim 14, wherein said dielectric film has a thickness of about k×λ/4n where k is an odd integer.

16. A semiconductor laser made with the method of claim 1.

17. A semiconductor laser comprising:
a lower mirror;
an upper mirror; and
an active layer sandwiched between said lower mirror and said upper mirror;
combined means for both suppressing laser light oscillations outside a defined oscillation region of said upper mirror and restricting exposure of said upper mirror to oxygen.

18. A method of controlling laser emission of a semiconductor laser device, said method comprising reflecting laser light from at least one reflective layer having thickness of at least about λ/2n, where λ is the wavelength of laser emissions and n is an index of refraction of said reflective layer, said reflective layer comprising an inner area and an outer area radially surrounding said inner area, wherein said inner area has a higher reflectivity than said outer area so that said emitting region is at least in part defined by said inner reflective layer.

19. A semiconductor laser comprising:
an active layer between upper and lower DBR mirrors; and
a reflective layer having a thickness of at least about λ/2n, where λ is the wavelength of laser emissions and n is an index of refraction of said reflective layer, said reflective layer comprising a first area having a first reflectivity factor with respect to light emitted by said active layer, and a second area radially surrounding said first area and having a second reflectivity factor with respect to said light emitted by said active layer;
wherein said second reflectivity factor is at least about three percent lower than said first reflectivity factor.

20. The semiconductor laser of claim 19, wherein said first area is thinner than said second area.

21. The semiconductor laser of claim 19, wherein said first area is thicker than said second area.

22. The semiconductor laser of claim 19, wherein said reflective layer consists essentially of a material selected from the group consisting of GaAs, AlGaAs, InGaP, AlGaInP or GaInAsP.

23. The semiconductor laser of claim 19, wherein
said semiconductor laser is formed on a GaAs substrate, and
said wavelength of laser emissions is in a range of about 700 to 1000 nm.

24. The semiconductor laser of claim 19, wherein
said semiconductor laser is formed on a GaAs substrate, and
said oscillation laser light has a wavelength in a range of about 1200 to 1600 nm.

25. A surface emitting laser device having a layer structure comprising a lower mirror, an active layer, and an upper mirror, said surface emitting laser device also comprising a current constriction layer in said lower mirror or said upper mirror, said surface emitting laser device comprising a semiconductor layer, said semiconductor layer comprising:
a first region exhibiting a first reflection factor, said first region being provided on said upper mirror wherein at least a portion of said first region is inside a boundary face of a current constriction region defined by said current constriction layer; and
a second region exhibiting a second reflection factor different from said first reflection factor.

26. The surface emitting laser device according to claim 25, wherein
said first region has a thickness that is substantially equal to (2i+1)/4n times a wavelength of the oscillation laser light, where n is a refractive index of said semiconductor layer, and i is an integer; and
said second region has a thickness that is substantially equal to 2j/4n time the wavelength of the oscillation laser light, where n is a refractive index of said semiconductor layer, and j is an integer.

27. The surface emitting laser device according to claim 25, wherein said semiconductor layer is covered with a dielectric film

28. The surface emitting laser device according to claim 27, wherein
said dielectric film has a refractive index smaller than that of said semiconductor layer, and
said dielectric film has a thickness that is substantially equal to 2k/4n times a wavelength of the oscillation laser light, where n is a refractive index of said dielectric film and k is an integer.

29. The surface emitting laser device according to claim 25, wherein
said semiconductor layer is covered with a dielectric film, said first region has a thickness that is substantially equal to 2i/4n times a wavelength of the oscillation laser light, where n is a refractive index of said semiconductor layer, and i is a integer;
said second region has a thickness that is substantially equal to (2j+1)/4n times the wavelength of the oscillation laser light, said dielectric film has a refractive index smaller than that of said semiconductor layer, where n is a refractive index of said semiconductor layer, and j is an integer; and
said dielectric film has a thickness that is substantially equal to (2k+1)/4n times the wavelength of the oscillation laser light, where n is a refractive index of said dielectric film and k is an integer.

30. The surface emitting laser device according to claim 25, wherein an electrode is provided on said semiconductor layer and outside a boundary face of a current constriction region defined by said current constriction layer.

31. The surface emitting laser device according to claim 25, wherein said semiconductor layer is formed of GaAs, AlGaAs, InGaP, AlGaInP or GaInAsP.

32. The surface emitting laser device according to claim 27, wherein said dielectric film is formed of SiN, SiO₂, Al₂O₃, TiO₂, AIN, or a-Si.

33. The surface emitting laser device according to claim 25, wherein
said layer structure is formed on a GaAs substrate, and
said oscillation laser light has a wavelength in a range of about 700 to 1000 nm.

34. The surface emitting laser device according to claim 25, wherein
said layer structure is formed on a GaAs substrate, and
said oscillation laser light has a wavelength in a range of about 1200 to 1600 nm.

35. A semiconductor laser comprising a lower mirror, an upper mirror, and an active layer sandwiched therebetween, said semiconductor laser further comprising a cap of material deposited on said upper mirror having two regions of different thickness, one of which is at least about λ/2n and one of which is at least about 3λ/4n, where λ is the wavelength of laser emissions and n is a refractive index of said active layer.

36. The semiconductor laser device of claim 35, wherein said cap of material consists essentially of a material selected from the group consisting of GaAs, AlGaAs, InGaP, AlGaInP or GaInAsP.

37. The semiconductor laser of claim 35, wherein a thickness difference of said two regions is about (j×λ)/4, where j is an odd integer.

38. A semiconductor laser comprising:
a plurality of layers of material forming a lower DBR mirror, an upper DBR mirror, and an active layer between said upper DBR mirror and said lower DBR mirror, wherein at least some of said layers comprise aluminum, and
an essentially aluminum free semiconductor layer formed over said upper DBR mirror, wherein said semiconductor layer has a recess formed therein.

39. The semiconductor laser of claim 38 wherein said semiconductor layer consists essentially of GaAs.

40. The semiconductor laser of claim 38 wherein said semiconductor layer has a thickness of at least about λ/2n where λ is the wavelength of laser emissions from said active layer and n is a refractive index of said semiconductor layer.

41. The semiconductor laser of claim 40 wherein said recess has a depth of about λ/4n below the top surface of said semiconductor layer.
